(19) United States
(12) Patent Application Publication
(10) Pub. No.: US 2024/0274770 A1
(43) Pub. Date: Aug. 15, 2024

(54) DISPLAY DEVICE AND MANUFACTURING METHOD THEREOF

(71) Applicant: Samsung Display Co., LTD., Yongin-si (KR)

(72) Inventor: Hui Won YANG, Yongin-si (KR)

(73) Assignee: Samsung Display Co., LTD., Yongin-si (KR)

(21) Appl. No.: 18/505,530

(22) Filed: Nov. 9, 2023

(30) Foreign Application Priority Data
Feb. 14, 2023 (KR) 10-2023-0019577

(51) Int. Cl. H01L 33/62; H01L 25/075; H01L 25/16

(52) U.S. Cl. CPC H01L 33/62; H01L 25/0753; H01L 25/167; H01L 2933/0066

(57) ABSTRACT

A display device includes a base layer, and a first backplane layer disposed on the base layer. The first backplane layer includes a lower backplane layer, an outer via layer disposed on the lower backplane layer, and an outer passivation layer disposed on the outer via layer. The outer passivation layer includes a first outer passivation layer and a second outer passivation layer disposed on the first outer passivation layer. The second outer passivation layer includes multiple holes overlapping the first outer passivation layer in a plan view.

### CROSS REFERENCE TO RELATED APPLICATION(S)

This application claims priority to and benefits of Korean Patent Application No. 10-2023-0019577 under 35 U.S.C. § 119, filed on Feb. 14, 2023, in the Korean Intellectual Property Office (KIPO), the entire contents of which are incorporated herein by reference.

### BACKGROUND

### 1. Technical Field

The disclosure relates to a display device and a manufacturing method thereof.

### 2. Description of the Related Art

As information technology has developed, the importance of a display device, which is a connection medium between a user and information, has been highlighted. Accordingly, research and development on a display device are continuously being conducted.

Meanwhile, a process for manufacturing a display device may include two or more steps, and various process equipment is used. Individual steps need to be clearly separated from each other spatially, but when individual steps are performed according to a process environment, it may be difficult to clearly separate respective spaces, and when performing a process, components of the display device may be damaged by the previously performed process equipment.

### SUMMARY

The disclosure provides a display device and a manufacturing method thereof that can prevent a risk of damaging components of the display device during a manufacturing process of the display device.

According to an embodiment of the disclosure, a display device may include a base layer, and a first backplane layer disposed on the base layer. The first backplane layer may include a lower backplane layer, an outer via layer disposed on the lower backplane layer, and an outer passivation layer disposed on the outer via layer, the outer passivation layer may include a first outer passivation layer and a second outer passivation layer disposed on the first outer passivation layer, and the second outer passivation layer may include a plurality of holes overlapping the first outer passivation layer in a plan view.

According to an embodiment, the second outer passivation layer may not contact the outer via layer.

According to an embodiment, the plurality of holes may expose the first outer passivation layer.

According to an embodiment, the plurality of holes may be arranged in a first loop structure and a second loop structure in a plan view, and the second loop structure may be disposed inside the first loop structure in a plan view.

According to an embodiment, the first loop structure and the second loop structure may have a quadrangular shape in a plan view.

According to an embodiment, the plurality of holes may have a same width in a direction.

According to an embodiment, the second outer passivation layer may include a protrusion surrounding at least a portion of the plurality of holes, and a ratio of a width of the protrusion and a thickness of the second outer passivation layer may be about 5:1.

According to an embodiment, each of the plurality of holes may form a groove, the groove may not expose the first outer passivation layer, and the second outer passivation layer may include a protrusion surrounding at least a portion of the groove in a plan view.

According to an embodiment, the groove may have a first width in a direction, the protrusion may have a second width in the direction, and the first width may be less than the second width.

According to an embodiment, the display device may further include a second backplane layer disposed on the base layer. The first backplane layer may be disposed on a front surface of the base layer, and the second backplane layer may be disposed on a rear surface of the base layer.

According to an embodiment, the display device may further include a pad connection wire electrically connecting a portion of the first backplane layer and a portion of the second backplane layer.

According to an embodiment of the disclosure, a manufacturing method of a display device may include forming a first backplane layer on a first surface of a base layer, inverting a stacked structure including the base layer and the first backplane layer, and forming a second backplane layer on a second surface of the base layer. The forming of the first backplane layer may include forming a lower backplane layer, forming an outer via layer on the lower backplane layer, and forming an outer passivation layer on the outer via layer, the forming of the outer passivation layer may include forming a first outer passivation layer and forming a second outer passivation layer on the first outer passivation layer, and the forming of the second outer passivation layer may include patterning the second outer passivation layer to have a plurality of holes overlapping the first outer passivation layer in a plan view.

According to an embodiment, after the forming of the first outer passivation layer, the first outer passivation layer may entirely cover the outer via layer.

According to an embodiment, the plurality of holes may have a circular shape, an elliptical shape, or a polygonal shape in a plan view.

According to an embodiment, the manufacturing method may further include disposing a light-emitting-element layer including a light emitting element on the first backplane layer. The first backplane layer may include a pixel circuit electrically connected to the light emitting element and a pad electrically connected to the pixel circuit, and the second backplane layer may include a wire electrically connecting a driving circuit portion disposed on the second backplane layer and the pad.

According to an embodiment, the forming of the second backplane layer may include contacting at least a portion of the first backplane layer with a process equipment for manufacturing the display device.

According to an embodiment, the second outer passivation layer may include a protrusion surrounding the plurality of holes, the first outer passivation layer and the process equipment may be physically spaced apart from each other by the protrusion, and the contacting of the at least a portion of the first backplane layer with the process equipment may include contacting at least a portion of the protrusion with the process equipment.

According to an embodiment of the disclosure, it may be possible to provide a display device and a manufacturing method thereof that can prevent a risk of damaging components of the display device during a manufacturing process of the display device.

### BRIEF DESCRIPTION OF THE DRAWINGS

FIG. 1 is a schematic plan view of a display device according to an embodiment.

FIG. 2 is a schematic plan view of a pixel according to an embodiment.

FIG. 3 is a schematic cross-sectional view of a display device according to an embodiment.

FIG. 4 is a schematic cross-sectional view of a first backplane layer according to an embodiment.

FIG. 5 is a schematic cross-sectional view of a first backplane layer according to an embodiment.

FIG. 6 is a schematic cross-sectional view of an outer via layer and an outer passivation layer according to an embodiment.

FIG. 7 is a schematic plan view of a second outer passivation layer according to an embodiment.

FIG. 8 is a schematic plan view of shapes of holes according to an embodiment.

FIG. 9 is a schematic plan view of shapes of holes according to another embodiment.

FIG. 10 is a schematic cross-sectional view taken along line A-A′ of FIG. 1.

FIG. 11 is a schematic flowchart of a manufacturing method of a display device according to an embodiment.

FIG. 12 to FIG. 19 are schematic cross-sectional views illustrating a manufacturing method of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Since the disclosure may be variously modified and have various forms, embodiments will be illustrated and described in detail in the following. This, however, by no means restricts the disclosure to the specific embodiments, and it is to be understood as embracing all included in the spirit and scope of the disclosure changes, equivalents, and substitutes.

Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the disclosure. Unless the context otherwise clearly indicates, words used in the singular include the plural, and the plural includes the singular.

In the disclosure, it should be understood that the term “include,” “comprise,” “have,” or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance. It will be understood that when an element such as a layer, film, region, area, or substrate is referred to as being “on” another element, it can be directly on the other element or intervening elements may also be present. In addition, in the specification, when a portion of a layer, film, region, area, plate, or the like is referred to as being formed “on” another portion, the formed direction is not limited to an upper direction but includes a lateral or lower direction. In contrast, when an element of a layer, film, region, area, plate, or the like is referred to as being “below” another element, it may be directly below the other element, or intervening elements may be present.

The terminology used herein is for the purpose of describing particular embodiments and is not intended to be limiting. As used herein, the singular forms, “a,” “an,” and “the” are intended to include the plural forms as well, unless the context clearly indicates otherwise. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

When an element, such as a layer, is referred to as being “on” or “connected to” another element or layer, it may be directly on, connected to, or coupled to the other element or layer or intervening elements or layers may be present. When, however, an element or layer is referred to as being “directly on” or “directly connected to” another element or layer, there are no intervening elements or layers present. To this end, the term “connected” may refer to physical, electrical, and/or fluid connection, with or without intervening elements. Further, the first direction DR1, the second direction DR2, and the third direction DR3 are not limited to three axes of a rectangular coordinate system, such as the x, y, and z axes, and may be interpreted in a broader sense. For example, the first direction DR1, the second direction DR2, and the third direction DR3 may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ.

Also, when an element is referred to as being “in contact” or “contacted” or the like to another element, the element may be in “electrical contact” or in “physical contact” with another element; or in “indirect contact” or in “direct contact” with another element.

Spatially relative terms, such as “below,” “lower,” “above,” “upper,” “over,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

The display surface may be parallel to a surface defined by a first direction DR1 and a second direction DR2. A normal direction of the display surface, i.e., a thickness direction of the display device DD, may indicate a third direction DR3. In this specification, an expression of “when viewed from a plane or on a plane” may represent a case when viewed in the third direction DR3. Hereinafter, a front surface (or a top surface) and a rear surface (or a bottom surface) of each of layers or units may be distinguished by the third direction DR3. However, directions indicated by the first to third directions DR1, DR2, and DR3 may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure relates to a display device and a manufacturing method thereof. Hereinafter, a display device and a manufacturing method thereof according to an embodiment will be described with reference to the accompanying drawings.

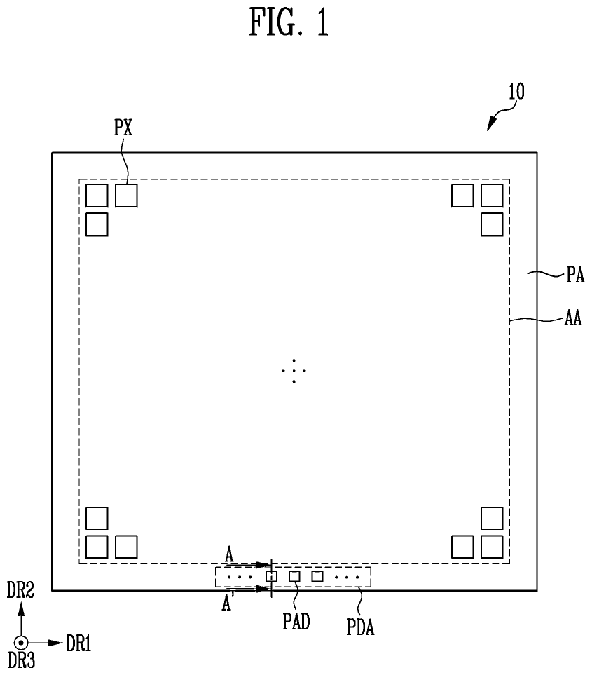

A display device 10 according to an embodiment will be described with reference to FIG. 1 to FIG. 10.

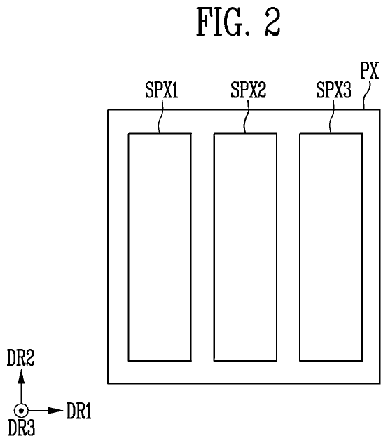

FIG. 1 is a schematic plan view of a display device 10 according to an embodiment. FIG. 2 is a schematic plan view of a pixel PX according to an embodiment.

Referring to FIG. 1, the display device 10 may output light. For example, the display device 10 may be a device displaying a moving image, a still image, or the like. The display device 10 may be used as a display screen of a portable electronic device such as a mobile phone, a smart phone, a tablet personal computer (PC), a smart watch, a watch phone, a mobile communication terminal, an electronic note, an electronic book, a portable multimedia players (PMP), a navigation device, an ultra mobile PC (UMPC), and the like, or various products such as a television set, a laptop computer, a monitor, a billboard, Internet of things (IOT), and the like. However, an application field of the display device 10 is not limited thereto.

The display device 10 may be formed as a flat surface having a quadrangular shape in a plan view. For example, the display device 10 may have a rectangular shape having a long side of a first direction DR1 and a short side of a second direction DR2 intersecting the first direction DR1 in a plan view. A corner at which the long side of the first direction DR1 and the short side of the second direction DR2 meet may be rounded to have a curvature or may be formed to have a right angle. The shape of the display device 10 is not limited to the quadrangular shape, and may be formed in a round shape such as another polygonal, circular, elliptical shape, or the like in a plan view. The display device 10 may be formed to be flat, but the disclosure is not limited thereto. For example, the display device 10 may include curved (or bent, folded, or rolled) portions that are formed at left and right ends and have a constant curvature, a variable curvature, or the like. The display device 10 may be formed bendable, foldable, rollable, or the like.

The display device 10 may include an active area AA and a peripheral area PA. The display device 10 may include a pad area PDA.

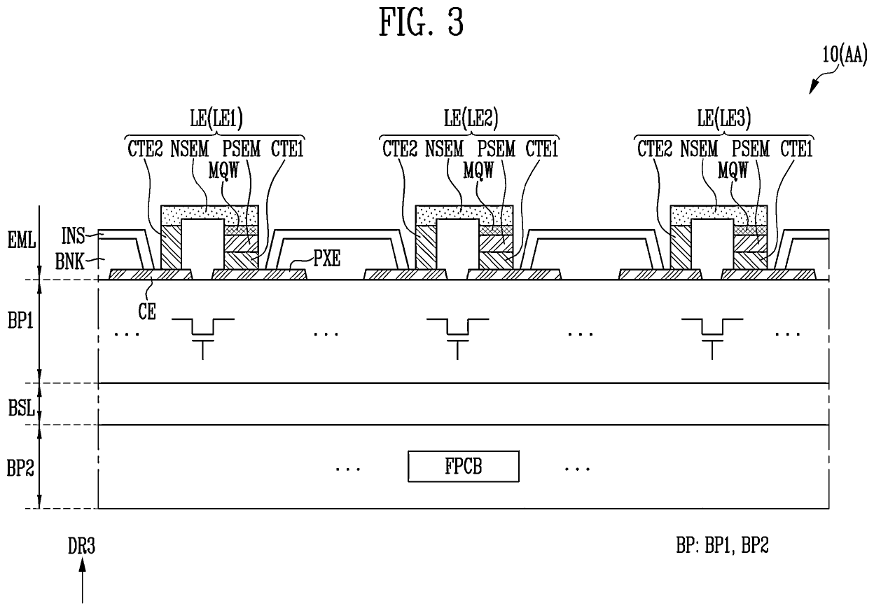

The active area AA may be an area in which a pixel PX is disposed. The active area AA may be a display area. The active area AA may be an area in which a light emitting element LE (see, e.g., FIG. 3) is disposed. For example, the pixel PX (or the light emitting element LE) may be disposed in the active area AA.

The peripheral area PA may be disposed adjacent to the active area AA. The peripheral area PA may be an area excluding the active area AA. The peripheral area PA may be an area in which the pixel PX is not disposed. In the peripheral area PA, a wire and a pad PAD electrically connected to the pixel PX may be disposed. The peripheral area PA may be a non-display area. The peripheral area PA may include a pad area PDA in which the pad PAD is disposed. The pad PAD may be electrically connected to a pixel circuit, and may be electrically connected to a driving circuit portion.

The display device 10 may include the pad PAD disposed in the pad area PDA. The pad PAD may be disposed at a side of the active area AA. However, the disclosure is not particularly limited thereto.

The display device 10 may further include pixels PX, scan wires extending in a direction (e.g., the first direction DR1), and data wires extending in another direction (e.g., the second direction DR2), to display an image. The pixels PX may be arranged in a matrix format in the first direction DR1 and the second direction DR2.

Each of the pixels PX may include multiple sub-pixels SPX1, SPX2, and SPX3 (see, e.g., FIG. 2). FIG. 2 illustrates that each of the pixels PX includes three sub-pixels SPX1, SPX2, and SPX3, for example, a first sub-pixel SPX1, a second sub-pixel SPX2, and a third sub-pixel SPX3, but the disclosure is not limited thereto.

The first sub-pixel SPX1, the second sub-pixel SPX2, and the third sub-pixel SPX3 may be connected to one of the data wires and at least one of the scan wires.

A shape of each of the first sub-pixel SPX1, the second sub-pixel SPX2, and the third sub-pixel SPX3 may be a rectangle, square, rhombus, or the like in a plan view. For example, each of the first sub-pixel SPX1, the second sub-pixel SPX2, and the third sub-pixel SPX3 may have a rectangular shape having short sides in the first direction DR1 and long sides in the second direction DR2 in a plan view as shown in FIG. 2. In another embodiment, a shape of each of the first sub-pixel SPX1, the second sub-pixel SPX2, and the third sub-pixel SPX3 may be a square or rhombus including sides having a same length in the first direction DR1 and the second direction DR2 in a plan view.

As shown in FIG. 2, the first sub-pixel SPX1, the second sub-pixel SPX2, and the third sub-pixel SPX3 may be arranged in the first direction DR1. In another embodiment, one of the second sub-pixel SPX2 and the third sub-pixel SPX3 and the first sub-pixel SPX1 may be arranged in the first direction DR1, and another one of the second sub-pixel SPX2 and the third sub-pixel SPX3 and the first sub-pixel SPX1 may be arranged in the second direction DR2.

In another embodiment, one of the first sub-pixel SPX1 and the third sub-pixel SPX3 and the second sub-pixel SPX2 may be arranged in the first direction DR1, and another one of the first sub-pixel SPX1 and the third sub-pixel SPX3 and the second sub-pixel SPX2 may be arranged in the second direction DR2. In another embodiment, one of the first sub-pixel SPX1 and the second sub-pixel SPX2 and the third sub-pixel SPX3 may be arranged in the first direction DR1, and another one of the first sub-pixel SPX1 and the second sub-pixel SPX2 and the third sub-pixel SPX3 may be arranged in the second direction DR2.

The first sub-pixel SPX1 may emit first light, the second sub-pixel SPX2 may emit second light, and the third sub-pixel SPX3 may emit third light. The first light may be light of a red wavelength band, the second light may be light of a green wavelength band, and the third light may be light of a blue wavelength band. The red wavelength band may be a wavelength band in a range of about 600 nm to about 750 nm, the green wavelength band may be a wavelength band in a range of about 480 nm to about 560 nm, and the blue wavelength band may be a wavelength band in a range of about 370 nm to about 460 nm, but the disclosure is not limited thereto.

Each of the first sub-pixel SPX1, the second sub-pixel SPX2, and the third sub-pixel SPX3 may include the light emitting element LE that emits light.

The light emitting element LE may be provided in various shapes. For example, the light emitting element LE may be an inorganic light emitting element including an inorganic material. In an embodiment, the light emitting element LE may be an organic light emitting diode (OLED). However, the disclosure is not limited thereto. Hereinafter, for better understanding and ease of description, an embodiment in which the light emitting element LE is an inorganic light emitting element including an inorganic semiconductor and is a flip-chip type micro light emitting diode (LED) will be described.

As shown in FIG. 2, an area of the first sub-pixel SPX1, an area of the second sub-pixel SPX2, and an area of the third sub-pixel SPX3 in a plan view may be substantially the same, but the disclosure is not limited thereto. At least one of the area of the first sub-pixel SPX1, the area of the second sub-pixel SPX2, and the area of the third sub-pixel SPX3 and another one of the area of the first sub-pixel SPX1, the area of the second sub-pixel SPX2, and the area of the third sub-pixel SPX3 may be different. In another embodiment, two of the area of the first sub-pixel SPX1, the area of the second sub-pixel SPX2, and the area of the third sub-pixel SPX3 may be substantially a same, and another one of the area of the first sub-pixel SPX1, the area of the second sub-pixel SPX2, and the area of the third sub-pixel SPX3 and two of the area of the first sub-pixel SPX1, the area of the second sub-pixel SPX2, and the area of the third sub-pixel SPX3 may be different. In another embodiment, the area of the first sub-pixel SPX1, the area of the second sub-pixel SPX2, and the area of the third sub-pixel SPX3 may be different from each other.

FIG. 3 is a schematic cross-sectional view of a display device 10 according to an embodiment. FIG. 3 schematically illustrates a cross-sectional structure of the display device 10 in the active area AA.

Referring to FIG. 3, the display device 10 may include a base layer BSL, a backplane layer BP, and a light-emitting-element layer EML.

The base layer BSL may be a base substrate or a base member for supporting the display device 10. The base layer BSL may be a rigid substrate made of a glass material or the like. In another embodiment, the base layer BSL may be a flexible substrate that is bendable, curvable, foldable, rollable, or the like, and the substrate may include an insulating material such as a polymer resin, such as a polyimide or the like, or the like.

The backplane layer BP may include metal layers for forming pixel circuits and wires, and insulating layers disposed between the metal layers.

The backplane layer BP may include a first backplane layer BP1 including a pixel circuit for driving the light emitting elements LE and a second backplane layer BP2 including rear wires electrically connected to a driving circuit portion FPCB.

The pixel circuits may include thin film transistors. The pixel circuits may further include storage capacitors. The pixel circuits may be electrically connected to the light emitting elements LE to provide electrical signals to the light emitting elements LE to emit light.

The first backplane layer BP1 may be disposed on the front surface of the base layer BSL. The first backplane layer BP1 may be disposed between the base layer BSL and the light-emitting-element layer EML. The second backplane layer BP2 may be disposed on the rear surface of the base layer BSL. In an embodiment, wires formed on the second backplane layer BP2 may electrically connect the driving circuit portion FPCB and the pads PAD. For example, the second backplane layer BP2 may include a wire for electrically connecting the driving circuit portion FPCB and the pad PAD.

The light-emitting-element layer EML may be disposed on the first backplane layer BP1. The light-emitting-element layer EML may include pixel electrodes PXE, cathode electrodes CE, and light emitting elements LE. Each of the first sub-pixel SPX1, the second sub-pixel SPX2, and the third sub-pixel SPX3 may include a light emitting element LE connected to a pixel electrode PXE and a cathode electrode CE. In an embodiment, the light emitting elements LE may include a first light emitting element LE1 that emits light of a first color and included in the first sub-pixel SPX1, a second light emitting element LE2 that emits light of a second color and included in the second sub-pixel SPX2, and a third light emitting element LE3 that emits light of a third color and included in the third sub-pixel SPX3. However, the disclosure is not necessarily limited thereto. For example, the first light emitting element LE1, the second light emitting element LE2, and the third light emitting element LE3 may emit light of a same color.

The pixel electrodes PXE and the cathode electrodes CE may be disposed on the first backplane layer BP1. Each of the pixel electrodes PXE may be electrically connected to the thin film transistor in the first backplane layer BP1. The pixel electrode PXE may be an anode electrode. Accordingly, a pixel voltage or an anode voltage controlled by the thin film transistor may be applied to the pixel electrode PXE.

Each of the cathode electrodes CE may be electrically connected to a power wire formed in the first backplane layer BP1. Accordingly, a power voltage of the power wire may be applied to the cathode electrodes CE.

The pixel electrodes PXE and the cathode electrodes CE may include a highly reflective metallic material such as a stacked structure of aluminum and titanium (Ti/Al/Ti), a stacked structure of aluminum and an ITO (ITO/Al/ITO), an APC alloy, a stacked structure of an APC alloy and an ITO (ITO/APC/ITO), and the like. The APC alloy may be an alloy of silver (Ag), palladium (Pd), and copper (Cu).

FIG. 3 illustrates that each of the light emitting elements LE is a flip-chip type micro LED in which a first contact electrode CTE1 and a second contact electrode CTE2 are disposed to face the pixel electrode PXE and the cathode electrode CE. However, the shape of the light emitting element LE is not necessarily limited thereto.

The light emitting element LE may include various semiconductor materials. For example, the light emitting element LE may include an inorganic material such as GaN or the like. A length in the first direction DR1, a length in the second direction DR2, and a length in the third direction DR3 of the light emitting element LE may be each in a range of several m to several hundred m. For example, the length in the first direction DR1, the length in the second direction DR2, and the length in the third direction DR3 of the light emitting element LE may be less than or equal to about 100 m.

Each light emitting element LE may be a light emitting structure including an n-type semiconductor NSEM, an active layer MQW, a p-type semiconductor PSEM, a first contact electrode CTE1, and a second contact electrode CTE2.

A portion of the n-type semiconductor NSEM may be disposed on the active layer MQW. A portion of the n-type semiconductor NSEM may be disposed on the second contact electrode CTE2. In an embodiment, a surface of the n-type semiconductor NSEM may face a display surface of the display device 10. The n-type semiconductor NSEM may be made of GaN doped with an n-type conductive dopant such as Si, Ge, Sn, or the like. However, the disclosure is not necessarily limited thereto.

The active layer MQW may be disposed on a portion of a surface of the n-type semiconductor NSEM. The active layer MQW may be interposed between the n-type semiconductor NSEM and the p-type semiconductor PSEM. The active layer MQW may include a material having a single or multiple quantum well structure. In case that the active layer MQW includes a material having a multi-quantum well structure, multiple well layers and multiple barrier layers may be alternately stacked each other. The well layer may be formed of InGaN, and the barrier layer may be formed of GaN or AlGaN, but the disclosure is not limited thereto. In another embodiment, the active layer MQW may have a structure in which a semiconductor material having large band gap energy and a semiconductor material having small band gap energy are alternately stacked each other, or may include group 3 to group 5 semiconductor materials depending on a wavelength band of light.

The p-type semiconductor PSEM may be disposed on a surface of the active layer MQW. The p-type semiconductor PSEM may be made of GaN doped with a p-type conductive dopant such as Mg, Zn, Ca, Se, Ba, or the like. However, the disclosure is not necessarily limited thereto.

The first contact electrode CTE1 may be disposed on the p-type semiconductor PSEM, and the second contact electrode CTE2 may be disposed on another portion of a surface of the n-type semiconductor NSEM. The another portion of the surface of the n-type semiconductor NSEM on which the second contact electrode CTE2 is disposed may be disposed to be spaced apart from the portion of the surface of the n-type semiconductor NSEM on which the active layer MQW is disposed.

The first contact electrode CTE1 and the pixel electrode PXE may be bonded to each other by a conductive adhesive member such as an anisotropic conductive film (ACF), an anisotropic conductive paste (ACP), or the like. In another embodiment, the first contact electrode CTE1 and the pixel electrode PXE may be bonded to each other by a soldering process.

A bank BNK covering an edge of the pixel electrode PXE and an edge of the cathode electrode CE may be disposed on the backplane layer BP (e.g., the first backplane layer BP1). The bank BNK may be formed as an organic film including an acryl resin, an epoxy resin, a phenol resin, a polyamide resin, a polyimide resin, or the like.

An insulating film INS may be disposed on the bank BNK. The insulating film INS may cover a portion of the pixel electrode PXE and a portion of the cathode electrode CE. The insulating film INS may be formed of an inorganic film, for example, a silicon nitride layer, a silicon oxynitride layer, a silicon oxide layer, a titanium oxide layer, an aluminum oxide layer, or the like.

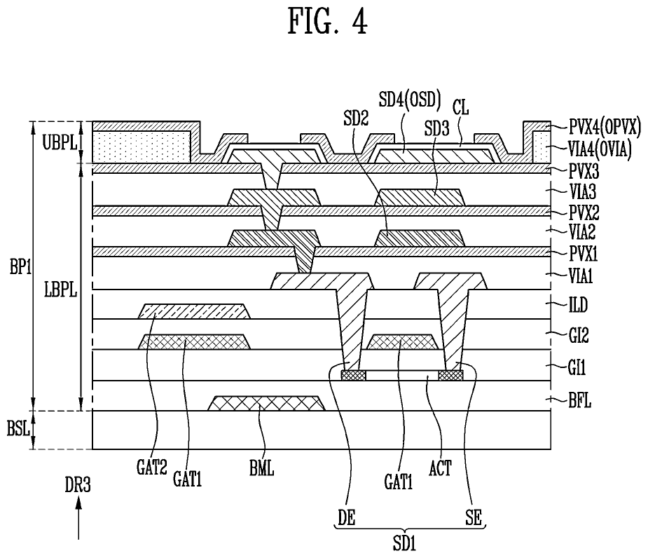

FIG. 4 is a schematic cross-sectional view of a first backplane layer BP1 according to an embodiment. FIG. 4 illustrates a structure of the first backplane layer BP1 according to an embodiment.

Referring to FIG. 4, the first backplane layer BP1 may include a lower backplane layer LBPL and an upper backplane layer UBPL. The upper backplane layer UBPL may be an outermost (or uppermost) structure in the first backplane layer BP1 in a thickness direction (for example, the third direction DR3) of the base layer BSL.

The lower backplane layer LBPL may include conductive layers and insulating layers disposed between an outer structure disposed at the outermost of the first backplane layer BP1 (for example, the upper backplane layer UBPL) and the base layer BSL.

The lower backplane layer LBPL may have a structure in which a least a portion is patterned in a structure in which a lower auxiliary electrode layer BML, a buffer layer BFL, an active layer ACT, a first gate insulating layer GI1, a first gate electrode layer GAT1, a second gate insulating layer GI2, a second gate electrode layer GAT2, an interlayer insulating layer ILD, a first interlayer conductive layer SD1 including a source electrode SE and a drain electrode DE, a first via layer VIA1, a first passivation layer PVX1, a second interlayer conductive layer SD2, a second via layer VIA2, a second passivation layer PVX2, a third interlayer conductive layer SD3, a third via layer VIA3, and a third passivation layer PVX3 are sequentially stacked.

For example, the aforementioned electrode layers may be patterned according to a structure to form the pixel circuit. For example, a portion of the active layer ACT, a portion of the first gate electrode layer GAT1, and a portion of the first interlayer conductive layer SD1 may form a driving transistor structure.

In an embodiment, the buffer layer BFL, the first gate insulating layer GI1, the second gate insulating layer GI2, the interlayer insulating layer ILD, the first passivation layer PVX1, the second passivation layer PVX2, and the third passivation layer PVX3 may include an inorganic material. In an embodiment, each of the first passivation layer PVX1, the second passivation layer PVX2, and the third passivation layer PVX3 may include a hole exposing a via layer disposed below each of the first passivation layer PVX1, the second passivation layer PVX2, and the third passivation layer PVX3.

In an embodiment, the active layer ACT may include a semiconductor. For example, the active layer ACT may include at least one of polysilicon, low temperature polycrystalline silicon (LTPS), amorphous silicon, and an oxide semiconductor.

In an embodiment, the first via layer VIA1, the second via layer VIA2, and the third via layer VIA3 may include an organic material.

In an embodiment, the lower auxiliary electrode layer BML, the first and second gate electrode layers GAT1 and GAT2, the first interlayer conductive layer SD1, the second interlayer conductive layer SD2, and the third interlayer conductive layer SD3 may include a conductive material.

The number and materials of the conductive layers and the insulating layers forming the lower backplane layer LBPL are not particularly limited to the above description, and the number and materials of the conductive layers and the insulating layers may be variously changed.

The upper backplane layer UBPL may include a fourth interlayer conductive layer SD4, a fourth via layer VIA4, a connection conductive layer CL, and a fourth passivation layer PVX4.

The fourth interlayer conductive layer SD4 may be an outer conductive layer OSD. The fourth via layer VIA4 may be an outer via layer OVIA. The fourth passivation layer PVX4 may be an outer passivation layer OPVX.

In an embodiment, the outer conductive layer OSD and the connection conductive layer CL may include a conductive material. In an embodiment, the connection conductive layer CL may include a transparent conductive material (e.g., an indium tin oxide (ITO)), but disclosure is not limited thereto.

The outer via layer OVIA may include an organic material, and the outer passivation layer OPVX may include an inorganic material. The outer passivation layer OPVX may cover the outer via layer OVIA. In an embodiment, the outer passivation layer OPVX may expose a portion of the connection conductive layer CL.

In an embodiment, the organic material may include at least one of an acrylic resin, an epoxy resin, a phenol resin, a polyamide resin, a polyimide rein, a polyester resin, a polyphenylenesulfide resin, and a benzocyclobutene. However, the disclosure is not limited thereto.

In an embodiment, the inorganic material may include at least one of a silicon nitride (SiNₓ), an aluminum nitride (AlNₓ), a titanium nitride (TiNₓ), a silicon oxide (SiOₓ), an aluminum oxide (AlOₓ), a titanium oxide (TiOₓ), a silicon oxycarbide (SiOₓC_{y}), and a silicon oxynitride (SiOₓN_{y}). However, the disclosure is not limited thereto.

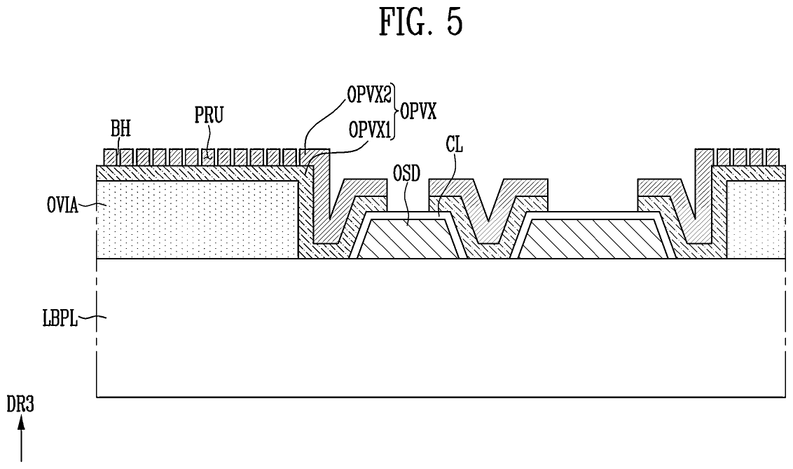

Hereinafter, the structures of the outer passivation layer OPVX and the outer via layer OVIA according to embodiments will be described in more detail with reference to FIG. 5 to FIG. 9. Descriptions that may be redundant to those described above are simplified or are not repeated.

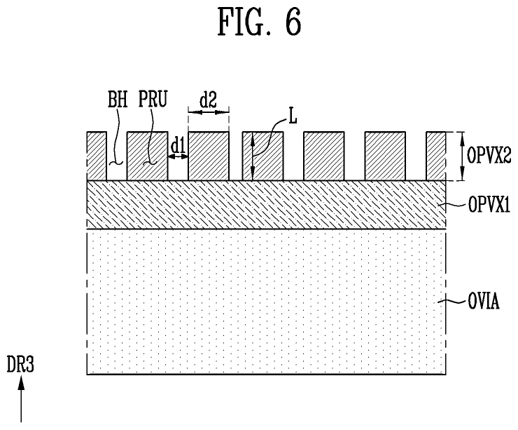

FIG. 5 is a schematic cross-sectional view of a first backplane layer BP1 according to an embodiment. FIG. 5 illustrates a schematic cross-sectional view of the first backplane layer BP1 of FIG. 4. FIG. 5 illustrates a schematic enlarged view of the outer passivation layer OPVX and the outer via layer OVIA. FIG. 6 is a schematic cross-sectional view of an outer via layer OVIA and an outer passivation layer OPVX according to an embodiment. FIG. 6 illustrates a schematic enlarged view of the outer via layer OVIA and the outer passivation layer OPVX of FIG. 5.

Referring to FIG. 5 and FIG. 6, the outer passivation layer OPVX may include a first outer passivation layer OPVX1 and a second outer passivation layer OPVX2. The first outer passivation layer OPVX1 and the second outer passivation layer OPVX2 may overlap the outer via layer OVIA in a plan view.

The first outer passivation layer OPVX1 may be disposed on the outer via layer OVIA. The first outer passivation layer OPVX1 may cover an entire area of the outer via layer OVIA. The first outer passivation layer OPVX1 may entirely cover the outer via layer OVIA. For example, the first outer passivation layer OPVX1 may not expose the outer via layer OVIA.

The second outer passivation layer OPVX2 may be disposed on the first outer passivation layer OPVX1. In an embodiment, the second outer passivation layer OPVX2 may cover a portion of the first outer passivation layer OPVX1, and may not cover another portion of the first outer passivation layer OPVX1. In an embodiment, the second outer passivation layer OPVX2 may contact the first outer passivation layer OPVX1. The second outer passivation layer OPVX2 may not contact the outer via layer OVIA. The second outer passivation layer OPVX2 may be physically spaced apart from the outer via layer OVIA in the thickness direction (or the third direction DR3). In an embodiment, the second outer passivation layer OPVX2 may include a hole BH that exposes a portion of a surface of the first outer passivation layer OPVX1. The second outer passivation layer OPVX2 may include a protrusion PRU, and the protrusion PRU may surround at least a portion of the hole BH.

However, the disclosure is not necessarily limited thereto. In another embodiment, the second outer passivation layer OPVX2 may entirely cover the first outer passivation layer OPVX1. In an embodiment, the second outer passivation layer OPVX2 may entirely contact the first outer passivation layer OPVX1. For example, a hole BH of the second outer passivation layer OPVX2 may form a groove that does not expose the first outer passivation layer OPVX1. The second outer passivation layer OPVX2 may include a protrusion PRU, and the protrusion PRU may surround at least a portion of the groove.

The first outer passivation layer OPVX1 and the second outer passivation layer OPVX2 may include an inorganic material. In an embodiment, the first outer passivation layer OPVX1 and the second outer passivation layer OPVX2 may include a same inorganic material. However, the disclosure is not necessarily limited thereto. For example, the first outer passivation layer OPVX1 and the second outer passivation layer OPVX2 may include different inorganic materials.

The second outer passivation layer OPVX2 may be patterned to form multiple holes BH. The holes BH may expose the first outer passivation layer OPVX1. At least a portion of the holes BH may overlap the first outer passivation layer OPVX1 in a plan view.

The first outer passivation layer OPVX1 and the second outer passivation layer OPVX2 may expose a portion of the connection conductive layer CL. Accordingly, the connection conductive layer CL may be electrically connected to wires.

In an embodiment, in an area exposing a portion of the connection conductive layer CL, the first outer passivation layer OPVX1 and the second outer passivation layer OPVX2 may have end portions that form a same surface. For example, the first outer passivation layer OPVX1 and the second outer passivation layer OPVX2 may include a same material, and have substantially corresponding etching ratios. Accordingly, in case that an etching process for exposing the connection conductive layer CL is performed, the first outer passivation layer OPVX1 and the second outer passivation layer OPVX2 may be etched to have openings of a same shape. However, the disclosure is not necessarily limited thereto.

The second outer passivation layer OPVX2 may include a protrusion PRU. For example, the protrusion PRU of the second outer passivation layer OPVX2 may surround at least a portion of the holes BH. A shape of the protrusion PRU of the second outer passivation layer OPVX2 is not particularly limited.

In an embodiment, since a structure including the protrusion PRU and the holes BH is formed in the outer passivation layer OPVX, a risk of being scratched in the horizontal direction (e.g., the first or second directions DR1 or DR2) may be prevented in case that the outer passivation layer OPVX contacts a process equipment in a process environment. Accordingly, a risk of damaging the outer via layer OVIA and the first backplane layer BP1 below the outer via layer OVIA may be prevented. Details on this will be described below.

The holes BH may each have a same width in a direction within an area in which the second outer passivation layer OPVX2 is disposed. The protrusions PRU may each have a same width in a direction within an area in which the second outer passivation layer OPVX2 is disposed.

The hole BH may have a first width d1 in the first direction DR1 or the second direction DR2. The protrusion PRU may have a second width d2 in the first direction DR1 or the second direction DR2. A depth of the hole BH and a thickness of the protrusion PRU in the third direction DR3 may be a same length L. The length L may be defined in the thickness direction of the second outer passivation layer OPVX2 (for example, in the third direction DR3). In an embodiment, in case that the hole BH forms a groove (instead of a through hole), the groove may have the first width d1 in the first direction DR1 or the second direction DR2).

The first width d1 may be less than the second width d2. The length L may be less than the second width d2. The length L and the second width d2 may have a ratio in a range of about 1:5 to about 1:6. However, the aforementioned ratio is not limited thereto.

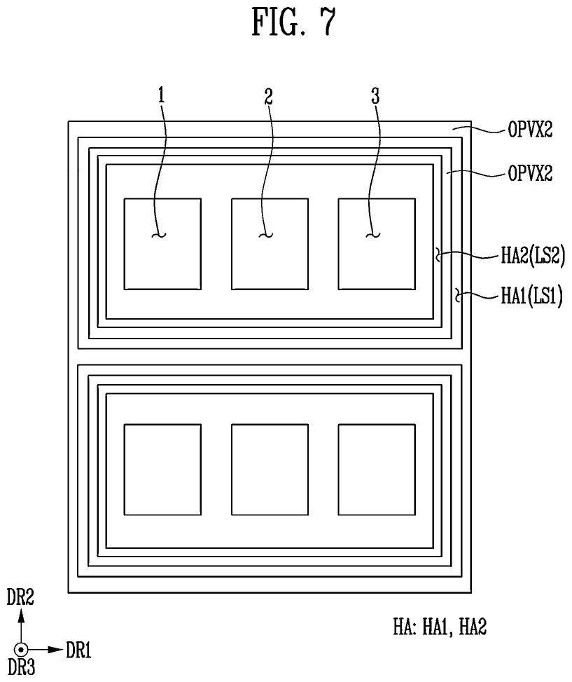

FIG. 7 is a schematic plan view of the second outer passivation layer OPVX2 according to an embodiment.

Referring to FIG. 7, the second outer passivation layer OPVX2 may include a hole area HA. The hole area HA may include a first hole area HA1 and a second hole area HA2. The first hole area HA1 and the second hole area HA2 may be an area in which the hole BH is disposed. FIG. 7 illustrates areas in which the sub-pixels SPX1, SPX2, and SPX3 are disposed as a first area 1, a second area 2, and a third area 3.

The hole BH may be arranged along a first loop structure LS1 and a second loop structure LS2. In an embodiment, the first hole area HA1 may have the first loop structure LS1. The second hole area HA2 may have the second loop structure LS2. In an embodiment, the first loop structure LS1 and the second loop structure LS2 may have a closed-loop structure in a plan view. However, the disclosure is not limited thereto, and the first loop structure LS1 and the second loop structure LS2 may have an open-loop structure in which at least a portion of the first loop structure LS1 and the second loop structure LS2 is opened. The second loop structure LS2 may be disposed inside the first loop structure LS1 in a plan view.

The second outer passivation layer OPVX2 may be patterned to have a quadrangular closed-loop holes BH that gradually become smaller in a plan view. However, the shape of the closed-loop hole is not limited to a quadrangular shape, and the second outer passivation layer OPVX2 may be patterned to have various shapes.

The first sub-pixel SPX1 may be disposed in the first area 1. The second sub-pixel SPX2 may be disposed in the second area 2. The third sub-pixel SPX3 may be disposed in the third area 3. However, the arrangement of the sub-pixels SPX1, SPX2, and SPX3 is not limited thereto. At least a portion of each of the first area 1, the second area 2, and the third area 3 may overlap the first outer passivation layer OPVX1 and the second outer passivation layer OPVX2 in a plan view.

In an embodiment, the first area 1, the second area 2, and the third area 3 may be disposed within the first loop structure LS1 in a plan view. In an embodiment, the first area 1, the second area 2, and the third area 3 may be disposed within the second loop structure LS2 in a plan view. For example, the hole BH may surround the areas 1, 2, and 3 in a plan view in which the sub-pixels SPX1, SPX2, and SPX3 are formed.

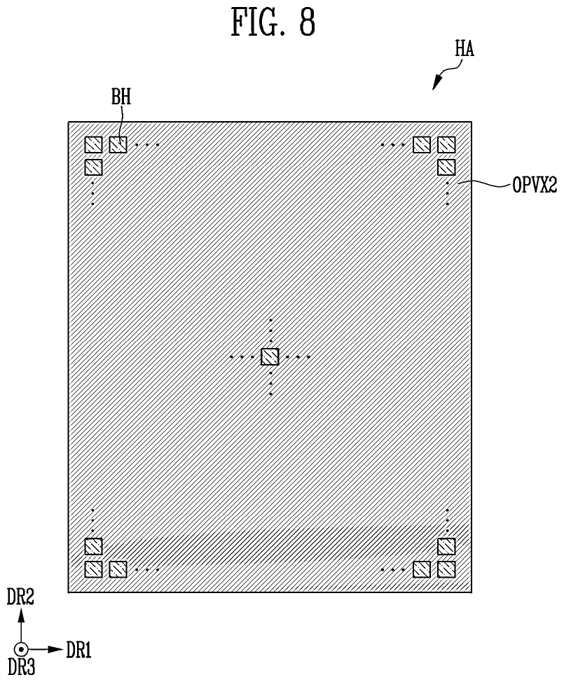

FIG. 8 is a schematic plan view of shapes of holes BH according to an embodiment. For better understanding and ease of description, in FIG. 8, the first area 1, the second area 2, and third area 3 are not illustrated.

Referring to FIG. 8, the holes BH may be arranged in a dot pattern. The holes BH may be arranged in a matrix in a row direction (for example, the first direction DR1) and a column direction (for example, the second direction DR2). For example, as the holes BH are arranged in the dot pattern, the outer passivation layer OPVX may have an embossed structure.

In an embodiment, the holes BH may have various shapes in a plan view. For example, the holes BH may have a quadrangular shape in a plan view. However, the disclosure is not limited thereto. For example, the holes BH may have various shapes such as polygonal shapes, circular shapes, and elliptical shapes in a plan view.

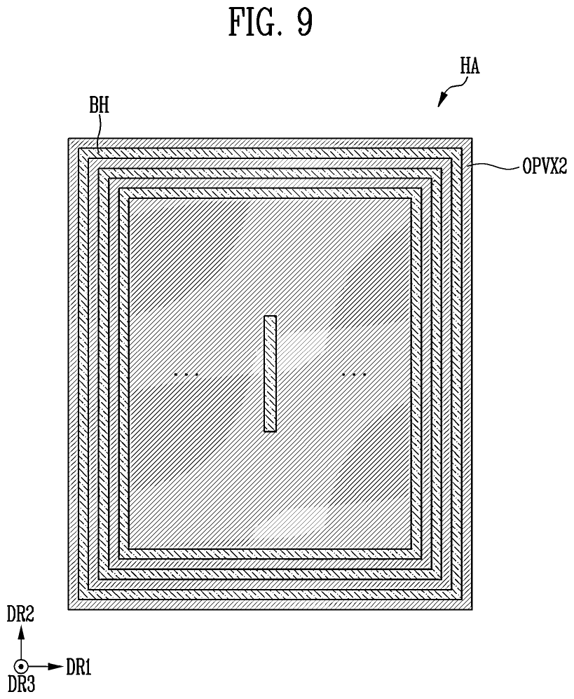

FIG. 9 is a schematic plan view of shapes of holes BH according to another embodiment. For better understanding and ease of description, in FIG. 9, the first area 1, the second area 2, and third area 3 are not illustrated.

Referring to FIG. 9, the hole BH may have a shape extending in a direction in a plan view. For example, the hole BH may have a loop shape in a plan view. The loop shape may be a polygonal shape, or may be a circular shape, an elliptical shape, or the like in a plan view.

The hole BH may be formed on the second outer passivation layer OPVX2. In an embodiment, the first outer passivation layer OPVX1 may not include the hole BH overlapping the outer via layer OVIA in a plan view, and the second outer passivation layer OPVX2 may include the hole BH overlapping the outer via layer OVIA in a plan view.

The second outer passivation layer OPVX2 may include the hole BH, and may be a discontinuous layer with respect to the first outer passivation layer OPVX1. For example, the first outer passivation layer OPVX1 and the second outer passivation layer OPVX2 may include a same material, but may be formed in different deposition processes. In another embodiment, the first outer passivation layer OPVX1 and the second outer passivation layer OPVX2 may include different materials. In an embodiment, an interface may be formed between the first outer passivation layer OPVX1 and the second outer passivation layer OPVX2.

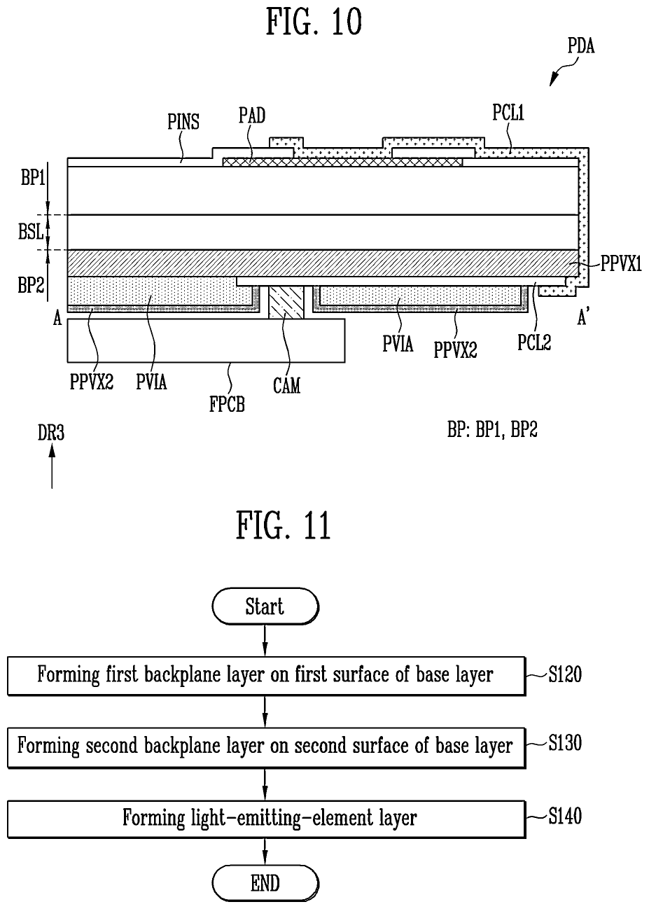

Hereinafter, a cross-sectional structure of the display device 10 in the pad area PDA according to an embodiment will be described with reference to FIG. 10.

FIG. 10 is a schematic cross-sectional view taken along line A-A′ of FIG. 1. FIG. 10 schematically illustrates areas adjacent to an edge of the display device 10. FIG. 10 schematically illustrates structures of portions of the base layer BSL and the backplane layer BP, and the light-emitting-element layer EML is not illustrated for better understanding and ease of description.

Referring to FIG. 10, the first backplane layer BP1 may include a pad PAD and a pad insulating layer PINS.

The pad PAD may be electrically connected to wires (e.g., data wires) of the display device 10. The wires may be formed by one or more of the conductive layers for forming the first backplane layer BP1. The pad PAD may include one or more layers. The pad PAD may be formed by one or more of the conductive layers for forming the first backplane layer BP1. However, the disclosure is not limited thereto.

The pad PAD may be disposed on a portion of the first backplane layer BP1, and may be covered by the pad insulating layer PINS. The pad insulating layer PINS may expose a portion of the pad PAD, and in the exposed area, the pad PAD and the first pad connection wire PCL1 may be electrically connected. The first pad connection wire PCL1 may be a side wire.

A portion of the first pad connection wire PCL1 may be formed on the second backplane layer BP2 that is disposed on the rear surface of the base layer BSL. The first pad connection wire PCL1 may be electrically connected to the second pad connection wire PCL2 formed on the second backplane layer BP2.

The second backplane layer BP2 may include a first lower passivation layer PPVX1, a lower via layer PVIA, and a second lower passivation layer PPVX2. The second backplane layer BP2 may include the second pad connection wire PCL2.

The second pad connection wire PCL2 may be disposed on the first lower passivation layer PPVX1, and electrically connect the first pad connection wire PCL1 and the driving circuit portion FPCB. For example, a portion of the second pad connection wire PCL2 may be electrically connected to the first pad connection wire PCL1, and another portion of the second pad connection wire PCL2 may be electrically connected to the driving circuit portion FPCB through a conductive adhesive member CAM.

The first lower passivation layer PPVX1 may be disposed on the rear surface of the base layer BSL, and may include an inorganic material. The lower via layer PVIA may be disposed on the first lower passivation layer PPVX1, and may include an organic material. The second lower passivation layer PPVX2 may be disposed on the lower via layer PVIA, and may include an inorganic material.

The conductive adhesive member CAM may be an anisotropic conductive film, an anisotropic conductive paste, or the like. The driving circuit portion FPCB may include a flexible circuit board. The driving circuit portion FPCB may include a source driving circuit for supplying data voltages to data wires.

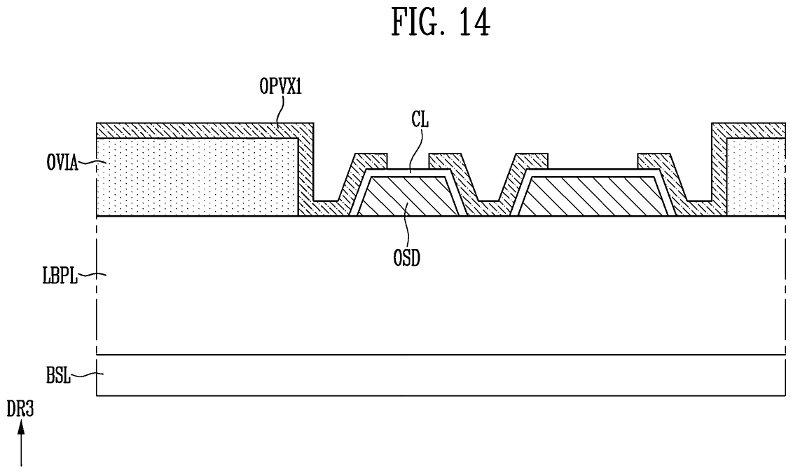

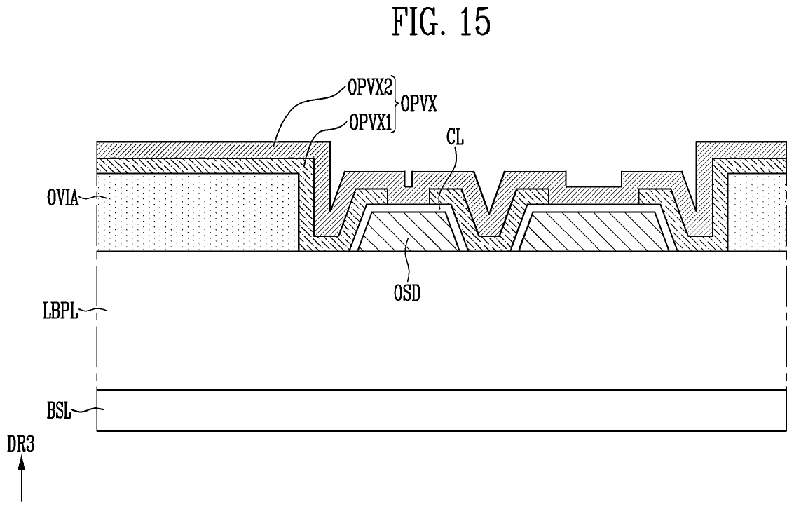

Hereinafter, a manufacturing method of a display device according to an embodiment will be described with reference to FIG. 11 to FIG. 19. Descriptions that may be redundant to those described above are simplified or are not repeated.

FIG. 11 is a schematic flowchart of a manufacturing method of a display device according to an embodiment. Referring to FIG. 11, a manufacturing method of the display device 10 according to an embodiment may include forming a first backplane layer on a first surface of a base layer (S120), forming a second backplane layer on a second surface of the base layer (S130), and forming (or disposing) a light-emitting-element layer (S140).

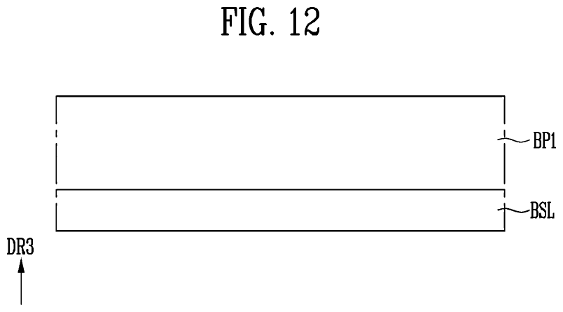

FIG. 12 to FIG. 19 are schematic cross-sectional views illustrating the manufacturing method of the display device according to an embodiment.

FIG. 12 illustrates a schematic cross-sectional view of a step S120 of forming the first backplane layer BP1 on the first surface of the base layer BSL. The first backplane layer BP1 may be a front backplane layer. In an embodiment, the base layer BSL may be a substrate for forming the first backplane layer BP1 and the second backplane layer BP2.

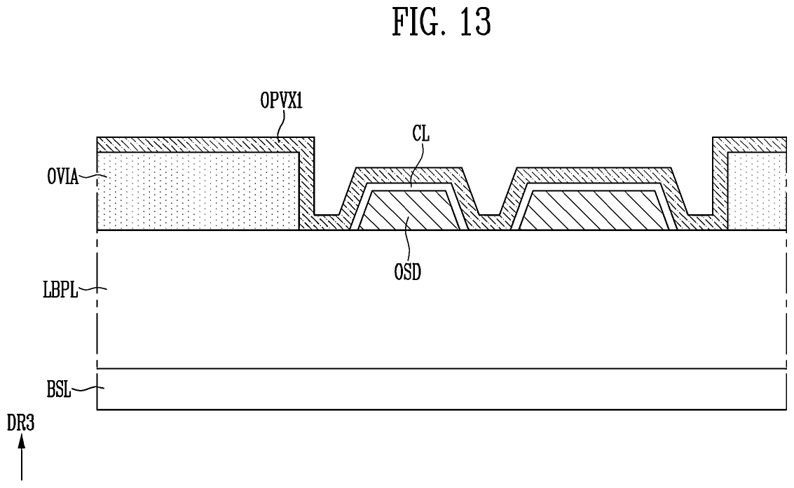

FIG. 13 to FIG. 16 illustrate schematic cross-sectional views of process steps of forming an outer via layer OVIA and an outer passivation layer OPVX in the manufacturing method of the display device.

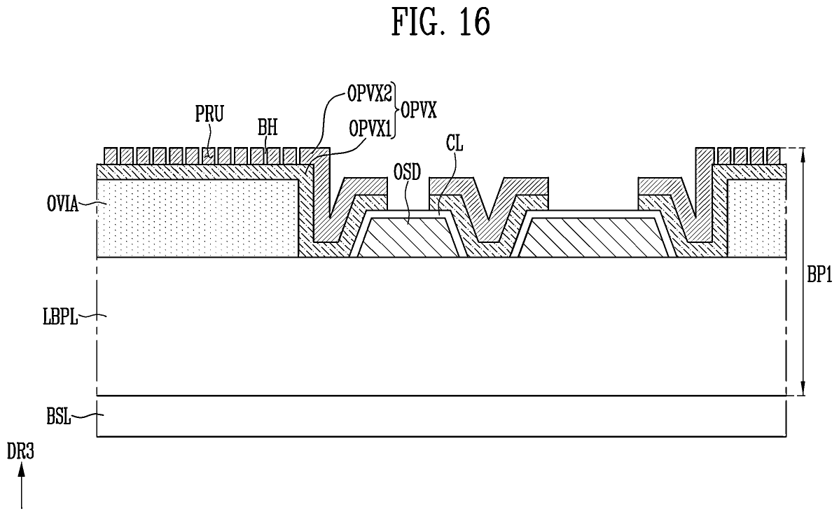

Hereinafter, step S120 of forming the first backplane layer BP1 on the first surface of the base layer BSL will be described with reference to FIG. 12 to FIG. 16. FIG. 12 to FIG. 16 are schematic cross-sectional views of a step of manufacturing the first backplane layer BP1. FIG. 16 schematically illustrates a cross-sectional structure of the display device 10 after the first backplane layer BP1 is formed.

In the step 120 of the forming of the first backplane layer BP1 on the first surface of the base layer BSL, the base layer BSL may be prepared, and conductive layers and insulating layers for forming the lower backplane layer LBPL may be patterned on the base layer BSL. The conductive layers and the insulating layers may be formed through a patterning process (e.g., a photolithography process) using a mask.

Referring to FIG. 13 to FIG. 16, the lower backplane layer LBPL may be formed on the base layer BSL, and the outer via layer OVIA may be formed on the lower backplane layer LBPL. The first outer passivation layer OPVX1 may be formed on the outer via layer OVIA. The first outer passivation layer OPVX1 may be deposited on the outer via layer OVIA.

In an embodiment, the first outer passivation layer OPVX1 may overlap the outer via layer OVIA and the connection conductive layer CL in a plan view. The first outer passivation layer OPVX1 may entirely cover the outer via layer OVIA.

In the step of the forming of the first outer passivation layer OPVX1 on the outer via layer OVIA, after the first outer passivation layer OPVX1 is deposited, the first outer passivation layer OPVX1 may be etched to expose at least a portion of the connection conductive layer CL.

After at least a portion of the first outer passivation layer OPVX1 is etched, the second outer passivation layer OPVX2 may be deposited on the first outer passivation layer OPVX1. The second outer passivation layer OPVX2 may be deposited to have a thickness, and the second outer passivation layer OPVX2 and the first passivation layer OPVX1 may have a same thickness in a thickness direction (for example, the third direction DR3). However, the disclosure is not necessarily limited thereto.

In an embodiment, a physical vapor deposition (PVD) process (e.g., a sputtering process), a chemical vapor deposition (CVD) process, an atomic layer deposition (ALD) process, or the like may be used to deposit the first outer passivation layer OPVX1 and the second outer passivation layer OPVX2. However, the disclosure is not limited thereto.

After the second outer passivation layer OPVX2 is deposited, at least a portion of the second outer passivation layer OPVX2 may be etched. For example, in the step of etching the second outer passivation layer OPVX2, at least a portion of the second outer passivation layer OPVX2 may be etched to expose at least a portion of the connection conductive layer CL. In the step of the etching of the second outer passivation layer OPVX2, at least another portion of the second outer passivation layer OPVX2 may be etched to form multiple holes BH. In an embodiment, the hole BH may expose the second outer passivation layer OPVX2. The hole BH may expose the first outer passivation layer OPVX1.

In an embodiment, the second outer passivation layer OPVX2 may be etched and may not expose the first outer passivation layer OPVX1. In the embodiment, the second outer passivation layer OPVX2 may entirely contact the first outer passivation layer OPVX1, and may be patterned to include the hole BH forming a groove. In an embodiment, the second outer passivation layer OPVX2 may have a groove that does not expose the first outer passivation layer OPVX1.

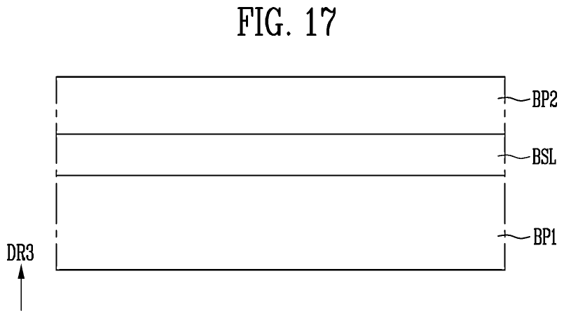

FIG. 17 is a schematic cross-sectional view of a step S130 of forming the second backplane layer BP2 on the second surface of the base layer BSL by inverting a structure (e.g., a stacked structure) including the base layer BSL and the first backplane layer BP1 after the step S120 of the forming of the first backplane layer BP1 on the first surface of the base layer BSL. After the step S120 of the forming of the first backplane layer BP1 on the first surface of the base layer BSL, a stacked structure including the base layer BSL and the first backplane layer BP1 may be inverted. After the step of the inverting of the stacked structure including the base layer BSL and the first backplane layer BP1, the second backplane layer BP2 may be formed S130.

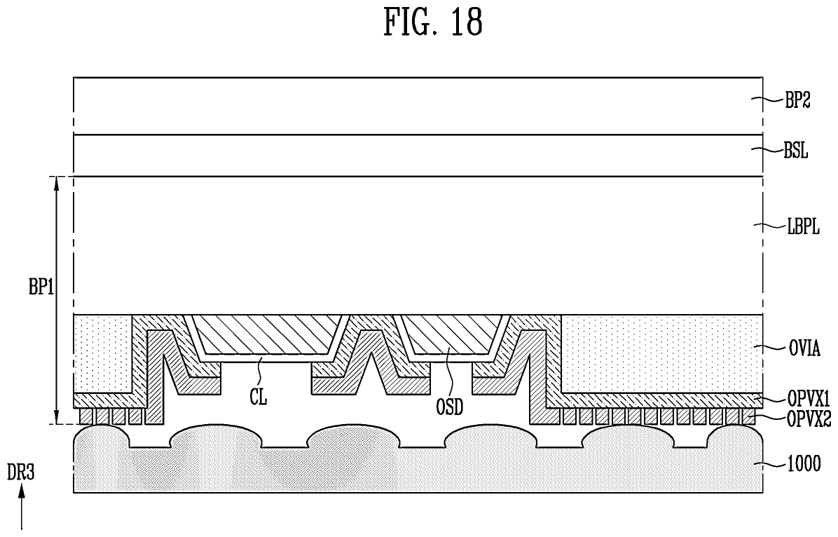

FIG. 18 is a schematic cross-sectional view of the step S130 of the forming of the second backplane layer BP2. The second backplane layer BP2 may be a rear backplane layer.

Referring to FIG. 17 and FIG. 18 in connection with FIG. 10, the second backplane layer BP2 may be formed on the base layer BSL. For example, the first lower passivation layer PPVX1, the lower via layer PVIA, the second lower passivation layer PPVX2, and the second pad connection wire PCL2 may be formed on the rear surface of the base layer BSL.

While the step S130 of the forming of the second backplane layer BP2 is being performed, the first backplane layer BP1 may contact a process equipment 1000. The process equipment 1000 may be an electrode in a chamber for forming an electric field in dry etching. However, the disclosure is not limited thereto, and the process equipment 1000 may be a manufacturing equipment for manufacturing a display device 10, such as an electrode in a plasma chamber, a nozzle of deposition equipment, or the like.

Experimentally, during the step S130 of the forming of the second backplane layer BP2 is performed, at least a portion of the first backplane layer BP1 may be damaged. For example, in case that some of the components of the first backplane layer BP1 and the process equipment 1000 contact each other, a physical impact may occur as the outer passivation layer OPVX is scratched in a horizontal direction (e.g., the first or second direction DR1 or DR2). In case that the outer passivation layer OPVX has a single-layered structure, the physical impact generated by contacting the process equipment 1000 may be applied to the outer via layer OVIA, so that cracks may occur in the first backplane layer BP1, and there may be a risk that the first backplane layer BP1 including the outer passivation layer OPVX and the outer via layer OVIA may be damaged.

In case that cracks are generated in the outer via layer OVIA, it may be difficult for the outer passivation layer OPVX to entirely cover the outer via layer OVIA, and accordingly, outgassing may occur between the cracks of the outer via layer OVIA and the outer passivation layer OPVX.

In case that the outgassing is excessively generated and the electrode layer (e.g., the second pad connection wire PCL2) is deposited on the rear surface, a defect in which a material for forming the electrode layer is abnormally film-formed may occur. For example, in case that the electrode layer on the rear surface includes an aluminum material, there may be a risk that the aluminum material may be abnormally formed due to the generated gas. Due to the outgassing, a risk of increasing surface resistance of electrode layers in the backplane layer BP may occur.

However, in an embodiment, the outer passivation layer OPVX may have a multi-layered structure including the first outer passivation layer OPVX1 and the second outer passivation layer OPVX2, wherein the first outer passivation layer OPVX1 may be formed to entirely cover the outer via layer OVIA, and the outermost second outer passivation layer OPVX2 may be patterned to form multiple holes BH, and accordingly, the second outer passivation layer OPVX2 may be manufactured to include the holes BH and the protrusion PRU.

In case that the outer passivation layer OPVX (e.g., the second outer passivation layer OPVX2) contacts the process equipment 1000, the hole BH and the protrusion PRU may prevent a risk that an external force is applied to the outer passivation layer OPVX in the horizontal direction. For example, a horizontal scratch risk to the outer passivation layer OPVX may be prevented. Accordingly, cracks caused due to a physical impact that may occur in case that the outer passivation layer OPVX and the process equipment 1000 contact each other may occur on the second outer passivation layer OPVX2, rather than on the first outer passivation layer OPVX1. Since the second outer passivation layer OPVX2 is formed outside the first outer passivation layer OPVX1, an influence due to the cracks may be prevented from being applied to the outer via layer OVIA. Accordingly, the risk of damaging the first backplane layer BP1 including the first outer passivation layer OPVX1 and the outer via layer OVIA may be prevented.

In a subsequent process, a portion of the second backplane layer BP2 and a portion of the first backplane layer BP1 may be electrically connected. For example, by forming the first pad connection wire PCL1, the pad PAD and the second pad connection wire PCL2 may be electrically connected. The process performed in the step of the electrically connecting of the pad PAD and the other wires may be a process of electrically connecting the pad PAD and other wires, and may be referred to as a side process.

In the side process, the first pad connection wire PCL1 may include a portion covering a side surface of the base layer BSL, and may electrically connect a portion of the first backplane layer BP1 (e.g., the pad PAD) and a portion of the second backplane layer BP2 (e.g., the second pad connection wire PCL2). The second pad connection wire PCL2 may be a wire electrically connected to the driving circuit portion FPCB in a subsequent process, and the pad PAD may be electrically connected to the driving circuit portion FPCB in a subsequent process.

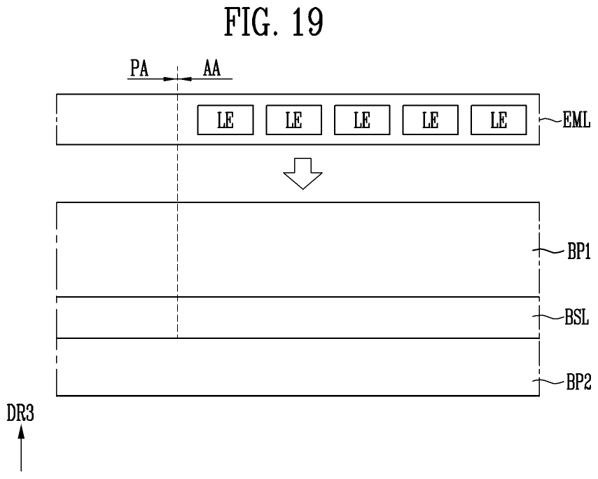

FIG. 19 is a schematic cross-sectional view illustrating a step S140 of disposing (or forming) the light-emitting-element layer EML on the first backplane layer BP1.

Referring to FIG. 19, in an embodiment, the light-emitting-element layer EML including the light emitting elements LE may be formed on the first backplane layer BP1. The light emitting elements LE may be disposed on the first backplane layer BP1 to form the active area AA.

In the step S140 of the disposing of the light-emitting element layer EML, the light emitting elements LE may be transferred to the first backplane layer BP1 in various methods. For example, the light emitting elements LE may be transferred by using a device using a transfer method such as a transfer method using a stamp, a transfer method using a laser, a transfer method using electrostatic force, a transfer method using magnetic force and electromagnetic force, and a transfer method using an adhesive. However, the disclosure is not limited thereto. In an embodiment, the light emitting elements LE may be disposed on the first backplane layer BP1 by forming two or more electrode structures, supplying the light emitting elements LE on the electrode structures, and forming an electric field between the electrode structures.

A time point at which the process performed in each step S120, S130, or S140 is performed is not particularly limited, and may be appropriately changed according to the process environment.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a base layer; and
a first backplane layer disposed on the base layer, wherein
the first backplane layer includes:
a lower backplane layer;
an outer via layer disposed on the lower backplane layer; and
an outer passivation layer disposed on the outer via layer,
the outer passivation layer includes:
a first outer passivation layer; and
a second outer passivation layer disposed on the first outer passivation layer, and
the second outer passivation layer includes a plurality of holes overlapping the first outer passivation layer in a plan view.

2. The display device of claim 1, wherein the second outer passivation layer does not contact the outer via layer.

3. The display device of claim 2, wherein the plurality of holes exposes the first outer passivation layer.

4. The display device of claim 2, wherein
the plurality of holes are arranged in a first loop structure and a second loop structure in a plan view, and
the second loop structure is disposed inside the first loop structure in a plan view.

5. The display device of claim 4, wherein the first loop structure and the second loop structure have a quadrangular shape in a plan view.

6. The display device of claim 2, wherein the plurality of holes have a same width in a direction.

7. The display device of claim 6, wherein
the second outer passivation layer includes a protrusion surrounding at least some of the plurality of holes, and
a ratio of a width of the protrusion and a thickness of the second outer passivation layer is about 5:1.

8. The display device of claim 1, wherein
each of the plurality of holes forms a groove,
the groove does not expose the first outer passivation layer, and
the second outer passivation layer includes a protrusion surrounding at least a portion of the groove in a plan view.

9. The display device of claim 8, wherein
the groove has a first width in a direction,
the protrusion has a second width in the direction, and
the first width is less than the second width.

10. The display device of claim 1, further comprising:
a second backplane layer disposed on the base layer, wherein
the first backplane layer is disposed on a front surface of the base layer, and
the second backplane layer is disposed on a rear surface of the base layer.

11. The display device of claim 10, further comprising:
a pad connection wire electrically connecting a portion of the first backplane layer and a portion of the second backplane layer.

12. A manufacturing method of a display device, comprising:
forming a first backplane layer on a first surface of a base layer;
inverting a stacked structure including the base layer and the first backplane layer; and
forming a second backplane layer on a second surface of the base layer, wherein
the forming of the first backplane layer includes:
forming a lower backplane layer;
forming an outer via layer on the lower backplane layer; and
forming an outer passivation layer on the outer via layer,
the forming of the outer passivation layer includes:
forming a first outer passivation layer; and
forming a second outer passivation layer on the first outer passivation layer, and
the forming of the second outer passivation layer includes patterning the second outer passivation layer to have a plurality of holes overlapping the first outer passivation layer in a plan view.

13. The manufacturing method of the display device of claim 12, wherein after the forming of the first outer passivation layer, the first outer passivation layer entirely covers the outer via layer.

14. The manufacturing method of the display device of claim 13, wherein the plurality of holes have a circular shape, an elliptical shape, or a polygonal shape in a plan view.

15. The manufacturing method of the display device of claim 13, further comprising:
disposing a light-emitting-element layer including a light emitting element on the first backplane layer, wherein
the first backplane layer includes:
a pixel circuit electrically connected to the light emitting element; and
a pad electrically connected to the pixel circuit, and
the second backplane layer includes a wire electrically connecting a driving circuit portion disposed on the second backplane layer and the pad.

16. The manufacturing method of the display device of claim 13, wherein the forming of the second backplane layer includes contacting at least a portion of the first backplane layer with a process equipment for manufacturing the display device.

17. The manufacturing method of the display device of claim 16, wherein
the second outer passivation layer includes a protrusion surrounding the plurality of holes,
the first outer passivation layer and the process equipment are physically spaced apart from each other by the protrusion, and
the contacting of the at least a portion of the first backplane layer with the process equipment includes contacting at least a portion of the protrusion with the process equipment.
